(19) United States
(12) Patent Application Publication
(10) Pub. No.: US 2012/0057356 A1
(43) Pub. Date: Mar. 8, 2012

(54) ELECTRICAL ISOLATION OF AN ION WIND FAN IN ENCLOSURE

(75) Inventors: Christopher A. Hizer, Campbell, CA (US); Rolan Sumook, San Jose, CA (US); Wei-min Jeff Wang, Palo Alto, CA (US)

(73) Assignee: Ventiva, Inc., Santa Clara, CA (US)

(21) Appl. No.: 12/913,646

(22) Filed: Oct. 27, 2010

Related U.S. Application Data
(60) Provisional application No. 61/380,175, filed on Sep. 3, 2010.

(51) Int. Cl. F21V 29/00; H05K 7/20; F28F 13/00; F28F 7/00

(52) U.S. Cl. 362/373; 165/185; 361/697; 165/120

(57) ABSTRACT

Ion wind fans can charge up or spark to the walls of an enclosure. In one embodiment, a heat source can be thermally managed using an ion wind fan by coupling the heat source to a heat spreader that also functions as a wall of an enclosure that contains the ion wind fan. A portion of the heat spreader is then electrically isolated from the ion wind fan, the portion being less than a minimum predetermined distance from the one or more emitter electrodes of the ion wind fan, to avid sparking between the emitters and the enclosure.

### CROSS-REFERENCE TO RELATED APPLICATIONS

This Application claims the priority benefit of U.S. Provisional Patent Application 61/380,175 entitled “Ion Wind Fan in Enclosure,” which is hereby fully incorporated by reference.

### FIELD OF THE INVENTION

The embodiments of the present invention are related ion wind fans, and in particular to a ion wind fans located in enclosures.

### BACKGROUND

It is well known that heat can be a problem in many electronics device environments, and that overheating can lead to failure of components such as integrated circuits (e.g. a central processing unit (CPU) of a computer) and other electronic components. Most electronics devices, from LED lighting to computers and entertainment devices, implements some form of thermal management to remove excess heat.

Heat sinks are a common passive tool used for thermal management. Heat sinks use conduction and convection to dissipate heat and thermally manage the heat-producing component. To increase the heat dissipation of a heat sink, a conventional rotary fan or blower fan has been used to move air across the surface of the heat sink, referred to generally as forced convection. Conventional fans have many disadvantages when used in consumer electronics products, such as noise, weight, size, and reliability caused by the failure of moving parts and bearings.

A solid-state fan using ionic wind to move air addresses the disadvantages of conventional fans. However, providing an ion wind fan that meets the requirements of consumer electronics devices presents numerous challenges not addressed by any currently existing ionic wind device.

### BRIEF DESCRIPTION OF THE DRAWINGS

FIG. 1 is a block diagram illustrating an ion wind fan implemented as part of thermal management of an electronic device;

FIG. 2A is a perspective view of an ion wind fan according to one embodiment of the present invention;

FIG. 2B is a widthwise cross-sectional view of the ion wind fan of FIG. 2A according to one embodiment of the present invention

FIG. 3 is a perspective view of an solid-state light bulb according to one embodiment of the present invention;

FIG. 4 is a top plan view of the light bulb of FIG. 3 according to one embodiment of the present invention;

FIG. 5 is an exploded view of the solid-state light bulb according to another embodiment of the present invention;

FIG. 6 is a cross-sectional view of a solid state light bulb according to one embodiment of the present invention;

FIG. 7 is a perspective view of a thermal module for use in a solid state light bulb according to one embodiment of the present invention;

FIG. 8 is a cross-sectional view of the thermal module of FIG. 7 according to one embodiment of the present invention;

FIG. 9 perspective view of a thermal module for use in a solid state light bulb according to one embodiment of the present invention;

FIG. 10 is a cross-sectional view of the thermal module of FIG. 9 according to one embodiment of the present invention;

FIG. 11A is a cross-sectional exploded view of an enclosure/air passage channel according to one embodiment of the present invention;

FIG. 11B is a cross-sectional assembled view of the enclosure/air passage channel of FIG. 11 according to one embodiment of the present invention;

FIG. 12 is a cross-sectional view of thermal module having end caps according to one embodiment of the present invention;

FIG. 13 is a cross-sectional view of a solid state light bulb according to one embodiment of the present invention;

FIG. 14 perspective view of a thermal module for use in a solid state light bulb according to one embodiment of the present invention;

FIG. 15 is a cross-sectional view of the thermal module of FIG. 14 according to one embodiment of the present invention;

FIG. 16 perspective view of a thermal module for use in a solid state light bulb according to one embodiment of the present invention; and

FIG. 17 is a cross-sectional view of the thermal module of FIG. 16 according to one embodiment of the present invention.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not necessarily be so limited; rather the principles thereof can be extended to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Ion wind or corona wind generally refers to the gas flow that is established between two electrodes, one sharp and the other blunt, when a high voltage is applied between the electrodes. The air is partially ionized in the region of high electric field near the sharp electrode. The ions that are attracted to the more distant blunt electrode collide with neutral (uncharged) molecules en route to the collector electrode and create a pumping action resulting in air movement. The high voltage sharp electrode is generally referred to as the emitter electrode or corona electrode, and the grounded blunt electrode is generally referred to as the counter electrode, getter electrode, or collector electrode.

The general concept of ion wind—also sometimes referred to as ionic wind and corona wind even though these concepts are not entirely synonymous—has been known for some time. For example, U.S. Pat. No. 4,210,847 to Shannon, et al., dated Jul. 1, 1980, titled “Electric Wind Generator” describes a corona wind device using a needle as the sharp corona electrode and a mesh screen as the blunt collector electrode. The concept of ion wind has been implemented in relatively large-scale air filtration devices, such as the Sharper Image Ionic Breeze.

### Example Ion Wind Fan Thermal Management Solution

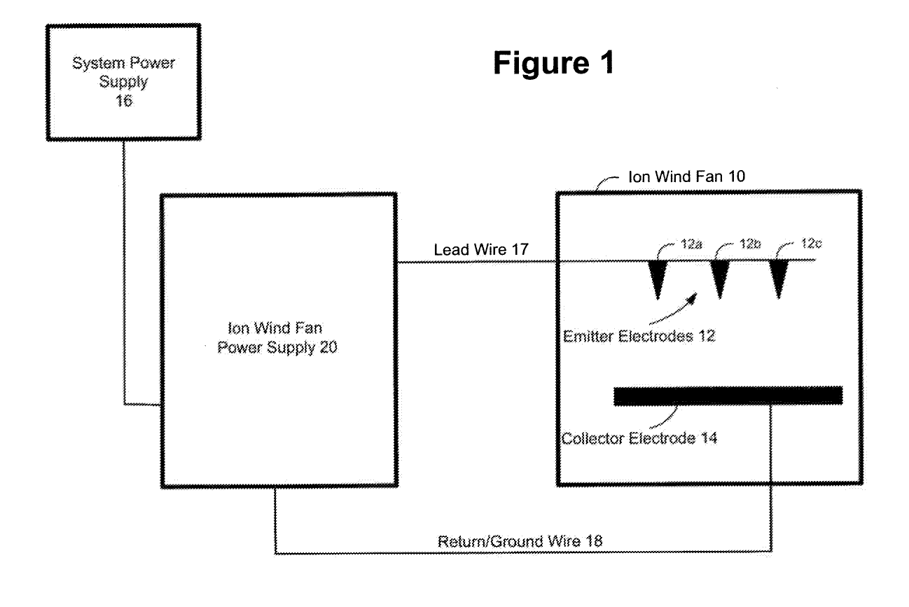

FIG. 1 illustrates an ion wind fan 10 used as part of a thermal management solution for an electronic device. As used in this Application, the descriptive term “ion wind fan,” is used to refer to any electro-aerodynamic pump, electro-hydrodynamic (EHD) pump, EHD thruster, corona wind device, ionic wind device, or any other such device used to move air or other gas. The term “fan” refers to any device that move air or some other gas. The term ion wind fan is meant to distinguish the fan from conventional rotary and blower fans. However, any type of ionic gas movement can be used in an ion wind fan, including, but not limited to corona discharge, dielectric barrier discharge, or any other ion generating technique.

An electronic device may need thermal management for an integrated circuit—such as a chip or a processor—that produces heat, or some other heat source, such as a light emitting diode (LED). Some example systems that can use an ion wind fan for thermal management include computers, laptops, gaming devices, projectors, television sets, set-top boxes, servers, NAS devices, memory devices, LED lighting devices, LED display devices, smart-phones, music players and other mobile devices, and generally any device having a heat source requiring thermal management.

The electronic device can have a system power supply 16 or can receive power directly from the mains AC via a wall outlet, Edison socket, or other outlet type. For example, in the case of a laptop computer, the laptop will have a system power supply such as a battery that provides electric power to the electronic components of the laptop. In the case of a wall-plug device such as a gaming device, television set, or LED lighting solution (lamp or bulb), the system power supply 16 will receive the 110V mains AC (in the U.S.A, 220V in the EU) current from an electrical outlet or socket.

The system power supply 16 for such a plug or screw-in device will also convert the mains AC into the appropriate voltage and type of current needed by the device (e.g., 10-50V DC for an LED lamp). While the system power supply 16 is shown as separate from the IWFPS 20, in some embodiments, one power supply can provide the appropriate voltage to both an ion wind fan 10 and other components of the electronic device. For example, a single driver can be design to drive the LEDs of and LED lamp and an ion wind fan included in the LED lamp.

The electronic device also includes a heat source (not shown), and may also include a passive thermal management element, such as a heat sink (also not shown). To assist in heat transfer, an ion wind fan 10 is provided in the system to help move air across the surface of the heat source or the heat sink, or just to generally circulate air (or some other gas) inside the device. In prior art systems, conventional rotary fans with rotating fan blades have been used for this purpose.

As discussed above, the ion wind fan 10 operates by creating a high electric field around one or more emitter electrodes 12 resulting in the generation of ions, which are then attracted to a collector electrode 14. In FIG. 1, the emitter electrodes 12 are represented as triangles as an illustration that they are generally “sharp” electrodes. However, in a real-world ion wind fan 10, the emitter electrodes 12 can be implemented as wires, shims, blades, pins, and numerous other geometries. Furthermore, while the ion wind fan 10 in FIG. 1 has three emitter electrodes (12a, 12b, 12c), the various embodiments of the present invention described herein can be implemented in conjunction with ion wind fans having any number of emitter electrodes 12.

Similarly, the collector electrode 14 is shown simply as a plate in FIG. 1. However, a real-world collector electrode 14 can have various shapes and will generally include openings to allow the passage of air. The collector electrode 14 can also be implemented as multiple collector electrode members (e.g., rods, washers) held at substantially the same potential. Furthermore, in a real world ion wind fan 10, the emitter electrodes 12 and the collector electrode 14 would be disposed on a dielectric chassis—sometimes referred to as an isolator element—that has also been omitted from FIG. 1 for simplicity and ease of understanding.

To create the high electric field necessary for ion generation, the ion wind fan 10 is connected to an ion wind power supply 20. The ion wind power supply 20 is a high-voltage power supply that can apply a high voltage potential across the emitter electrodes 12 and the collector electrode 14. The ion wind fan power supply 20 (hereinafter sometimes referred to as “IWFPS”) is electrically coupled to and receives electrical power from the system power supply 16. Usually for electronic devices, the system power supply 16 provides low-voltage direct current (DC) power. For example, a laptop computer system power supply would likely output approximately 5-12V DC, while the power supply for an LED light fixture would likely output approximately 20-70V DC.

The high voltage DC generated by the IWFPS 20 is then electrically coupled to the emitter electrodes 12 of the ion wind fan 10 via a lead wire 17. The collector electrode 14 is connected back to the IWFPS 20 via return/ground wire 18, to ground the collector electrode 14 thereby creating a high voltage potential across the emitters 12 and the collector 14 electrodes. The return wire 18 can be connected to a system, local, or absolute high-voltage ground using conventional techniques.

While the system shown in and described with reference to FIG. 1 uses a positive DC voltage to generate ions, ion wind can be created using AC voltage, or by connecting the emitters 12 to the negative terminal of the IWFPS 20 resulting in a “negative” corona wind. Embodiments of the present invention are not limited to positive DC voltage ion wind. Furthermore, while the IWFPS 20 is shown to receive power from a system power supply 30, in other embodiment, the IWFPS 20 can receive power directly from an outlet.

The IWFPS 20 may include other components. Furthermore, in some embodiments, some of the components listed above may be omitted or replaced by similar or equivalent circuits. For example, the IWFPS 20 is described only as an example. Many different kinds and types of power supplies can be used as the IWFPS 20, including power supplies that do not have a transformers or other components shown in FIG. 1. The components described need not be physically separate, and may be combined on a single printed circuit board (PCB).

As described partially above, ion wind is generated by the ion wind fan 10 by applying a high voltage potential across the emitter 12 and collector 14 electrodes. This creates a strong electric field around the emitter electrodes 12, strong enough to ionize the air in the vicinity of the emitter electrodes 12, in effect creating a plasma region. The ions are attracted to collector electrode 12, and as they move in air gap along the electric field lines, the ions bump into neutral air molecules, creating airflow. On a real world collector electrode 14, air passage openings (not shown) allow the airflow to pass through the collector 14 thus creating an ion wind fan.

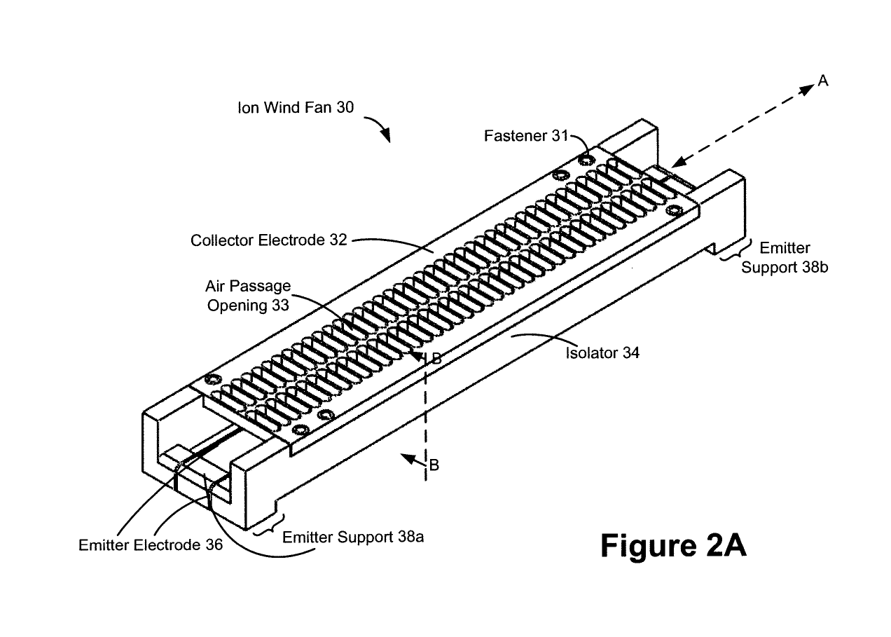

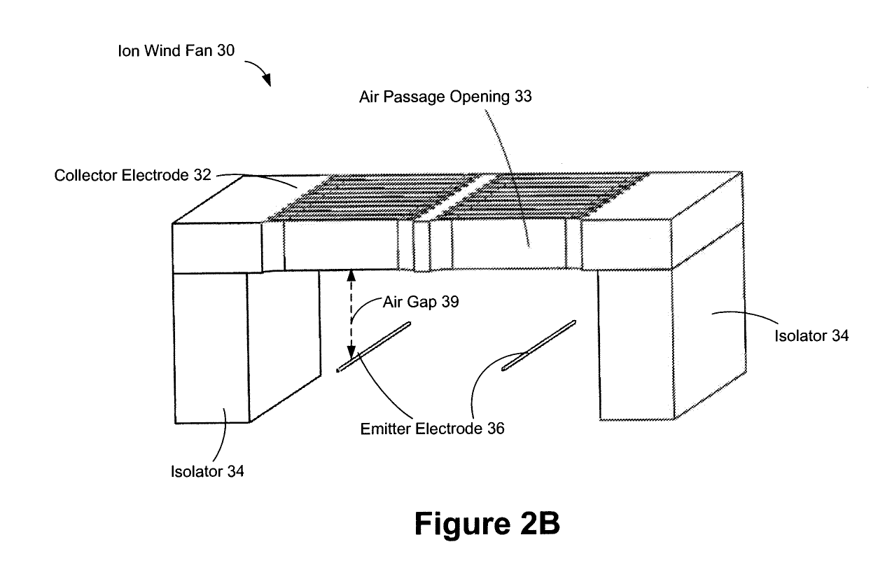

An example of such an ion wind fan is now described with reference to FIGS. 2A and 2B. FIG. 2A is a perspective view of an example ion wind fan 30. The ion wind fan 30 includes a collector electrode 32 having air passage openings 33 to allow airflow. This example ion wind fan 30 has two emitter electrodes 36 implemented as wires, thus implementing what is sometimes referred to as a “wire-to-plane” configuration.

The collector electrode 32 and the emitter electrodes 36 are both supported by an isolator 34. The isolator is made of a dielectric material, such as plastic, ceramic, and the like. The “isolator” component is thusly named as it functions to electrically isolate the emitter electrodes 36 from the collector electrode 32, and to physically support these electrodes. As such the isolator also can establish the spatial relationship between the electrodes, sometimes referred to under the rubric of electrode geometry. The isolator 34 can be made from one integral piece—as shown in FIG. 2A—or it can be made of multiple parts and pieces.

In the embodiment shown in FIG. 2A, the collector electrode is attached to the isolator using a fastener 31. The fastener 31 in FIG. 2 is a stake, but any other attachment method can be used, including but not limited to screws, hooks, glue, and so on. Similarly, the particular method of attachment of the emitter electrodes 36 is not essential to the embodiments of the present invention. The emitter electrodes 36 can be glued, staked, screwed, tied, held by friction, or attached in any other way to the isolator 34.

The ion wind fan 30—in the embodiment shown in FIG. 2A—is substantially rectangular in top view. The longitudinal axis of the ion wind fan 30 is denoted with the dotted arrow labeled “A.” The ion wind fan 30 has two ends opposite each other along the longitudinal axis. The emitter electrodes 36 are suspended between the two ends of the ion wind fan 30.

In one embodiment, the emitter electrodes 36 are supported at the ends of the ion wind fan 30 by an emitter support 38 portion of the isolator 34. The emitter support 38a at the left end of the ion wind fan 30 is most visible in FIG. 2A. The emitter support 38a is a portion of the isolator that physically supports the emitter electrodes 36. In one embodiment, the emitter electrodes 36 are suspended (in tension) between the two emitter supports 38 at the two ends of the ion wind fan 30.

In the embodiment shown in FIG. 2A, the isolator 34 has two elongated members oriented along the longitudinal direction that support the collector electrode 32, and the two elongated members are held joined by two cross-members that support the emitter electrodes 36. In one embodiment, these cross-members are oriented perpendicular to the elongated members (and thus the longitudinal axis). In FIG. 2A, these cross-members make up the emitter supports 38.

Thus, while in one embodiment the emitter support 38a is a substantially rectangular solid portion of the isolator 34 that connects the two elongated side portions of the isolator 34, in other embodiments the emitter supports 38 can have many other shapes and orientations. For example, a part of the center portion of the emitter support 38a between the emitter electrodes 36 could be cut away without substantially affecting the function of the emitter support 38a.

The emitter support 38a is shown as extending to the end of the ion wind fan 30. However, in other embodiments, the emitter support 38a can end before the end of the ion wind fan 30. The emitter support 38a is also shown as having a curved section at its outside edge to smooth out the 90 degree bend in the wire emitter electrodes 36. This is an optional feature not related to the embodiments of the present invention described herein.

Indeed, the actual attachment of the emitter electrodes 36 to either the emitter support 38 or some other portion of the isolator 34 is not material to the embodiments of the present invention, and therefore will not be discussed in much detail for simplicity and ease of understanding. The emitter electrodes 36 are shown as extending downward from the left end of the ion wind fan 30 and they are connected to the power supply via some wire or bus, as is the collector electrode 32. The emitter supports 38 need not have any particular shape of contact with the emitter electrodes 36. The emitter supports 38 are the portions of the isolator 34 that define the physical spatial relationship between the emitter electrodes 34 and other components of the ion wind fan 30. How exactly the emitter supports 38 are in contact with the emitter electrodes 36 (grooves, stakes, friction, posts, welding, epoxy) are not germane to the embodiments of the present invention.

FIG. 2B further illustrates the example ion wind fan 30 shown in FIG. 2A. FIG. 2B is a perspective cross sectional view of the ion wind fan 30 along the line B-B shown in FIG. 2A. The emitter electrodes 36 are suspended in air, and held a substantially constant air gap 39 distance away from the collector electrode 32.

Though wire sag and other emitter irregularities will create some variance, in one embodiment the air gap 39 between the emitter electrodes 36 and the bottom plane of the collector electrode 32 is substantially constant (within a 5% variation). In other embodiments, the air gap 39 can be more variable. The size of the air gap 39 is dependent on the spatial relationship between the electrodes established by the emitter supports 38 (which are not visible in FIG. 2B).

### Light Bulb Having Separated Light Source and Power Supply Thermal Management

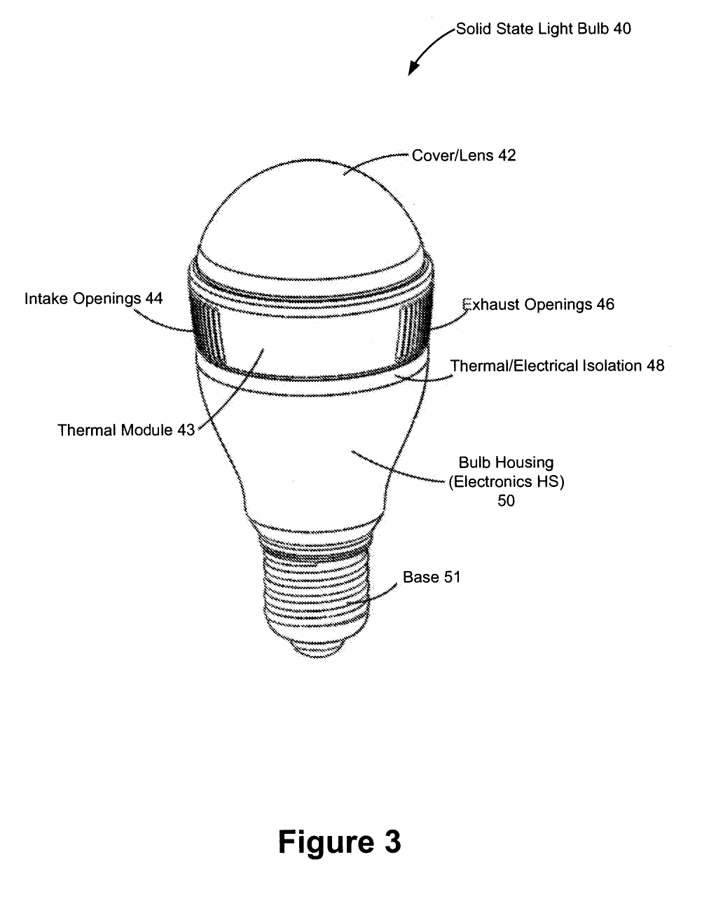

One embodiment of the present invention is now described with reference to FIG. 3. FIG. 3 is a perspective view of a solid-state (LED) light bulb 40. While in one embodiment, the light source (light device(s)) are made of light-emitting diodes (LEDs), in other embodiment, various other solid-state and/or semiconductor light sources can be used. The light sources reside under a cover/lens 42 generally made of a transparent or translucent material so that the light from the bulb 40 can illuminate a space outside of the bulb 40.

The opposite end of the bulb 40 is a base 51 that connects the bulb 40 to a light socket or other power source. In one embodiment, the base 51 is a screw-type base designed to mate with Edison-type light sockets. However, in other embodiments, other types of electrical connectors can be used. In some portions of the descriptions, the bulb 40 can be said to have a longitudinal axis intersecting the center of the base 51 and the center of the lens 42.

The base 51 connects to a bulb housing 50 that defines—in one embodiment—the outside shape of approximately half of the light bulb 40. The bulb housing 50 is hollow on the inside and contains a cavity to store the various electronics components of the light bulb 40. In turn, the cover 42 is connects to a thermal module 43 that thermally manages the light sources (such as the LEDs) of the light bulb 40. The thermal module 43 includes an ion wind fan 30 located in a channel that allows air to move between the intake openings 44 and the exhaust openings 46.

In one embodiment, the thermal management of the light sources is physically separated from the thermal management of the bulb electronics. In some embodiments, the light sources can operate at significantly higher temperatures than the electronics components. Thus thermally separating them and separately managing their temperatures allows bulb 40 to be operated with a significant temperature disparity between the light sources and the bulb electronics.

Prior art LED light bulbs do not have ion wind fans, and typically have a single heat sink that is thermally coupled to both the LEDs and the LED power supply electronics. Thus, heat from the electronics and the LEDs is dissipated using the same heat sink.

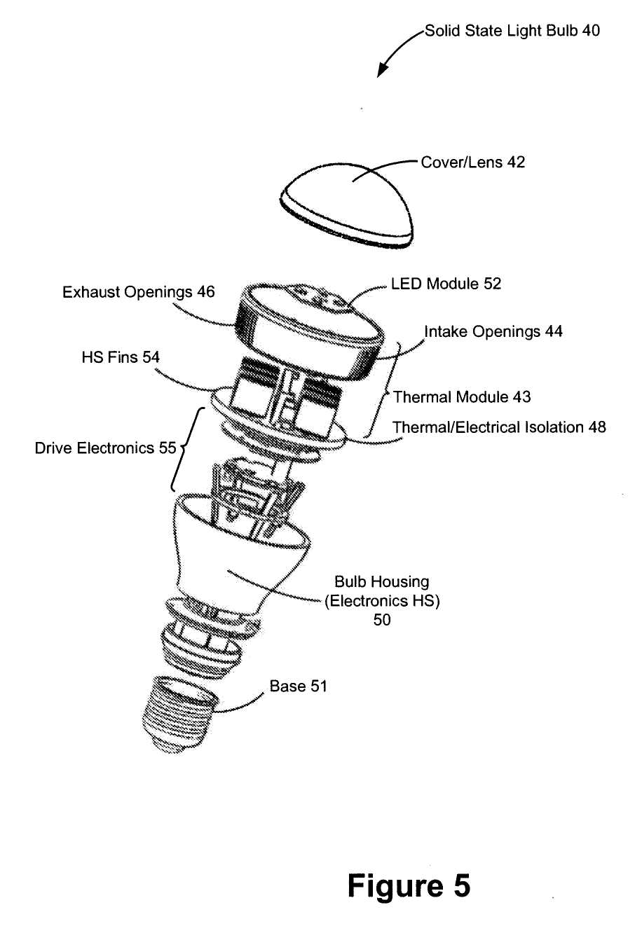

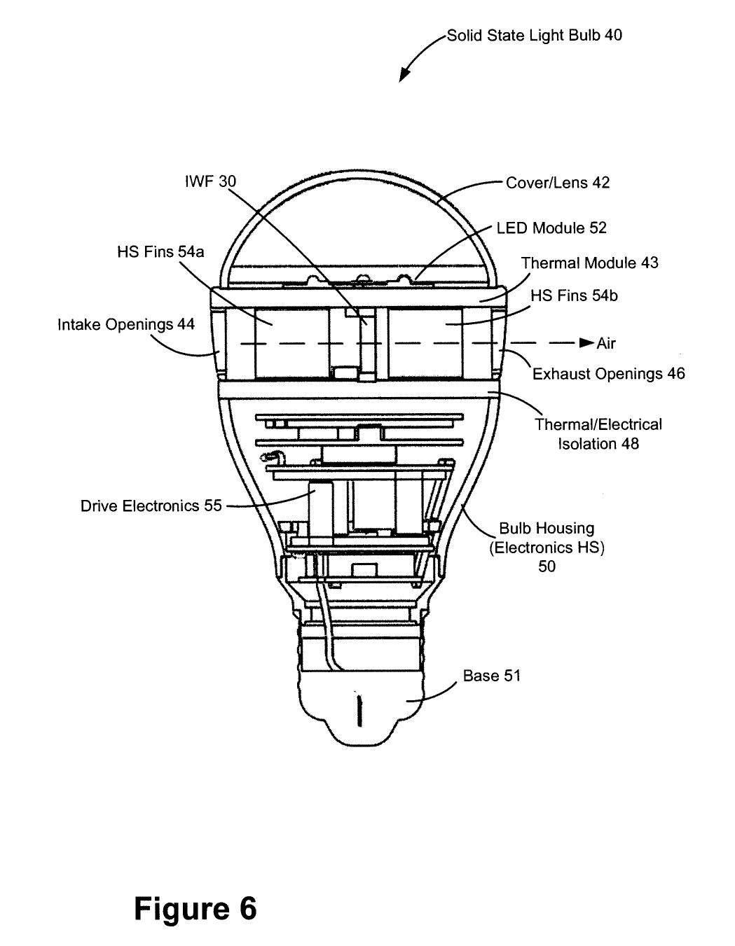

In one embodiment, the present invention includes a thermal isolation 48 between the thermal module 43 used to thermally manage the light sources and the bulb housing 50, which can be used as a heat sink for the bulb electronics. This is discussed in more detail with respect to FIGS. 5 and 6 further below.

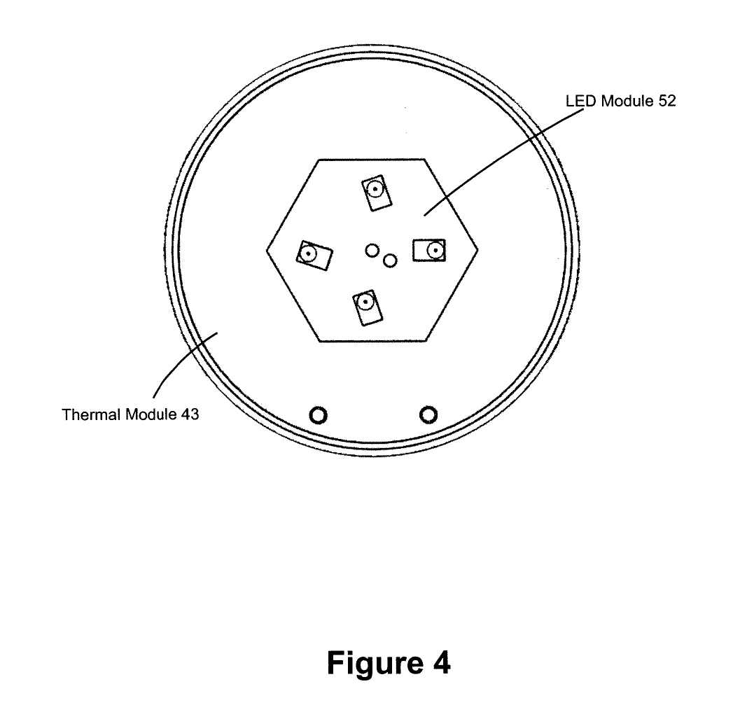

FIG. 4 is a top view of the light bulb 40 from the top of the lens 42 towards the base 51, sighting down the longitudinal axis of the light bulb 40. It shows and LED module 52 containing several LEDs located under the cover 42. The LED module 52 can be any type of LED or other solid-state light source, such as those designed and manufactured by BrideLux, Phillips, Sharp, and various other manufacturers. The LED module 52 is thermally coupled to the thermal module 43.

FIG. 5 is an exploded view of the light bulb 40. Visible are the cover/lens 42, the base 51, and the bulb housing 50, which are not described again Also shown is that the LED module 52 is thermally coupled to the thermal module 43 by directly mounting the LED module to a flat heat spreader portion of the thermal module 43. The attachment can be done using a thermal adhesive or other thermally efficient coupling.

The thermal module 43 includes the module housing consisting of a flat round heat spreader and walls extending from the edges of the heat spreader. The walls also define the outside of the bulb 40 for the portion of the bulb 40 that is the thermal module 43. The thermal module has a set of intake 44 and exhaust 46 openings, and a channel defined therebetween. An ion wind fan, and one or more sets of heat sink fins 54 are located inside the channel, as will be explained further below.

The bulb electronics 55 are also shown in FIG. 5. The bulb electronics 55 are housed inside the cavity defined by the bulb housing 50, the base 51, and the thermal/electrical isolation 48. In one embodiment, the thermal/electrical isolation 48 is a round disk made of a dielectric material (for electrical isolation) that is also a poor conductor of heat (i.e., has low thermal conductivity for thermal isolation).

FIG. 6 is a cross-section of the bulb 40 of FIG. 5. The airflow is labeled with a dashed line. In this embodiment, the thermal module 43 includes two set of fins 54a,b with the ion wind fan 30 located therebetween. The thermal isolation 48 plate separates the thermal management of the electronics 55 (with are thermally managed using the bulb housing 50 doubling as a heat sink) from the thermal management of the LED module 52.

As is apparent from FIG. 6, the LED module 52 is thermally managed by heat transferring from the LED module 52 to the thermal module 43. In one embodiment, this includes the sides of the intake 44 and exhaust 446 openings, in addition to the top “heat spreader” portion of the thermal module 43 and the sets of fins 54 of the thermal module. In the embodiment shown in FIG. 6, the heat sink fins 54 are attached and thermally coupled to the heat spreader, but in other embodiments the heat sink fins 54 can be integrally formed, as will be described further below.

There can be various structures and embodiment to implement separated thermal management of a light source and the light-source power supply. In one embodiment, two separate heat sinks are used. One heat sink is thermally coupled to the light source and the other is thermally coupled to the power supply. The two heat sinks are thermally isolated from each other, meaning they are not in physical metal-to-metal contact. They may however occupy the same physical space with some minimal air gap between the two heat sinks that creates significant thermal resistance between the two heat sinks.

In one embodiment, the power supply heat sink is also the heat sink to which the power supply for an ion wind fan is thermally coupled, while the ion wind fan is used to create forced convection for the other heat sink to which the LED/light source is thermally coupled. In yet other embodiments, the ion wind fan can be configured to create forced convection to both heat sinks, but the two heat sinks would still remain substantially thermally isolated and at significantly different temperatures. For example, in one embodiment, the LEDs may operate at 80-110 degrees C., while the power supplies temperature is maintained at between 20-50 degrees C. Various other temperature ranges an be used and the present invention is not limited to any specific temperature range.

### Parallel Air-Passage Openings on Round/Cylindrical Housings

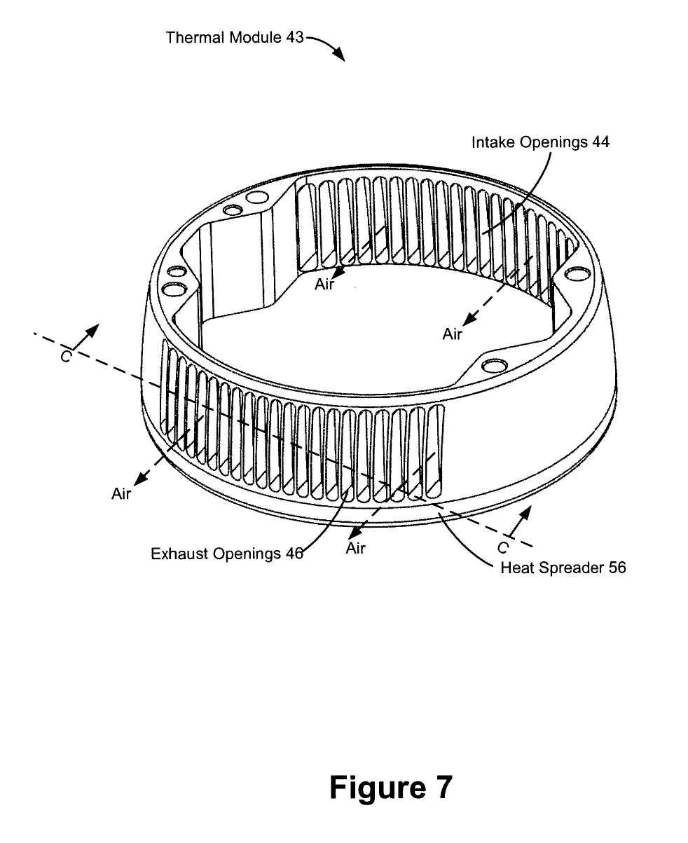

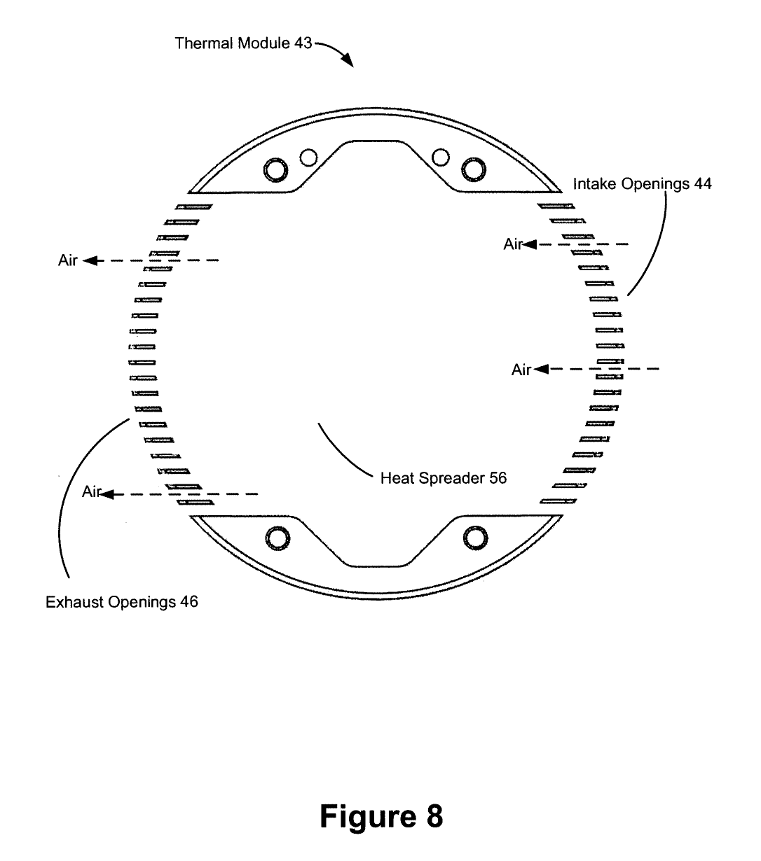

One embodiment of the intake 44 and exhaust 46 openings is now described with reference to FIGS. 7 and 8. FIG. 7 shows one embodiment of the thermal module 43. In this embodiment the heat spreader portion and the round wall portion are made of one integral piece, and the openings are found on the wall portion. However, in other embodiments, the intake 44 and exhaust 46 openings would be located on the bulb body. Such an embodiment is described for example in U.S. patent application Ser. No. 12/902,836 entitled Touch-Safe Solid-State Light Bulb Having Ion Wind Fan, filed on Oct. 12, 2010 and assigned to the assignee of the present Application, which is hereby fully incorporated by reference.

In one embodiment, even though the cross-section of a bulb-shaped housing is round, the intake 44 and exhaust openings have parallel walls. FIG. 8 is a cross-section of the thermal module 43 at the C-C line. In FIG. 8, the vertical walls of the intake and exhaust openings are parallel with each other. When creating openings in a round object, openings are generally created radially, so that if extended, the openings would reach the center of the circle. That is, openings in circular, cylindrical, or spherical object are generally created perpendicular to the surface, in the direction of the radius of the circle.

However, in one embodiment of the present invention, the sets of intake 44 and exhaust 46 openings are parallel to each other. In one embodiment, the one or two openings of a set of openings that are in the middle of the set of openings can be radial (towards the central longitudinal axis of the bulb 40 and perpendicular to such central axis), and the other openings in the set are parallel to the central opening.

In some embodiments, the openings 44, 46 are not perfectly parallel, but substantially parallel. In yet other embodiments, the openings in a set of openings are not parallel, but at angles that are less that the angle of a radial opening. The shape of the openings could be square, oval, slit-like (as shown), rectangular, or any other shape.

In one embodiment, the openings are also substantially parallel with the direction of airflow. In the embodiments described herein, the ion wind fan 30 generated an airflow that is substantially laminar and perpendicular to the plane of the collector electrode. By making the openings parallel with the airflow and thus with one another, the airflow is smoother and faster, with fewer transitions.

In FIGS. 7 and 8, both intake 44 and exhaust 46 openings are parallel within the sets and with each other. In other embodiments, only the set of intake openings 44 is parallel, while the exhaust openings 46 can be radial. In yet other embodiments, only the set of exhaust openings 46 is parallel, while the intake openings 44 can be radial. In yet other embodiments, only some of the openings in a set are parallel, while others are not. In the Figures, all openings are the same size, in other embodiments, variable size openings can be used (e.g., more central openings being larger or smaller than openings at the sides of each set of openings).

### Thermal Module Isolation

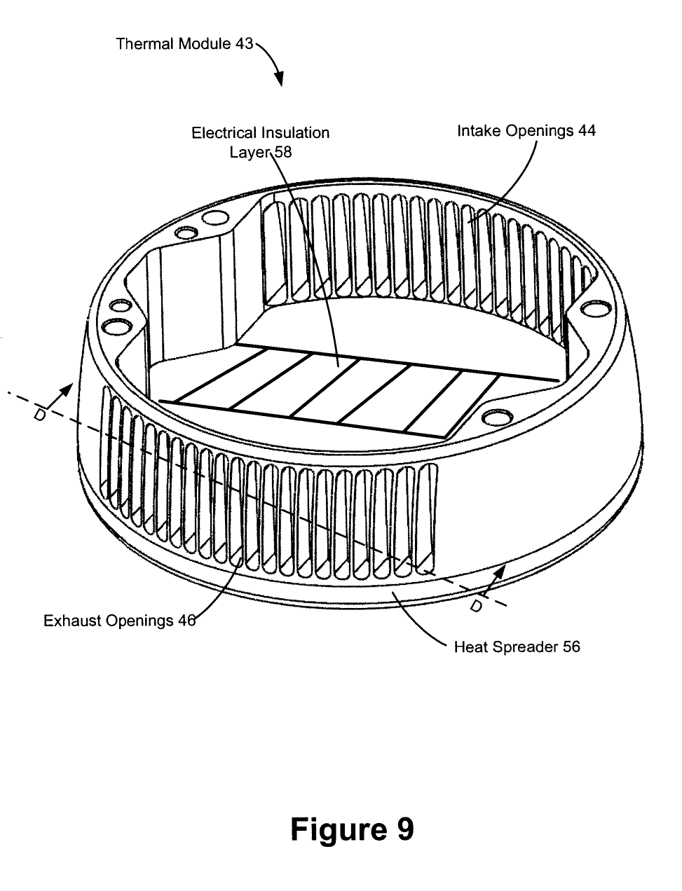

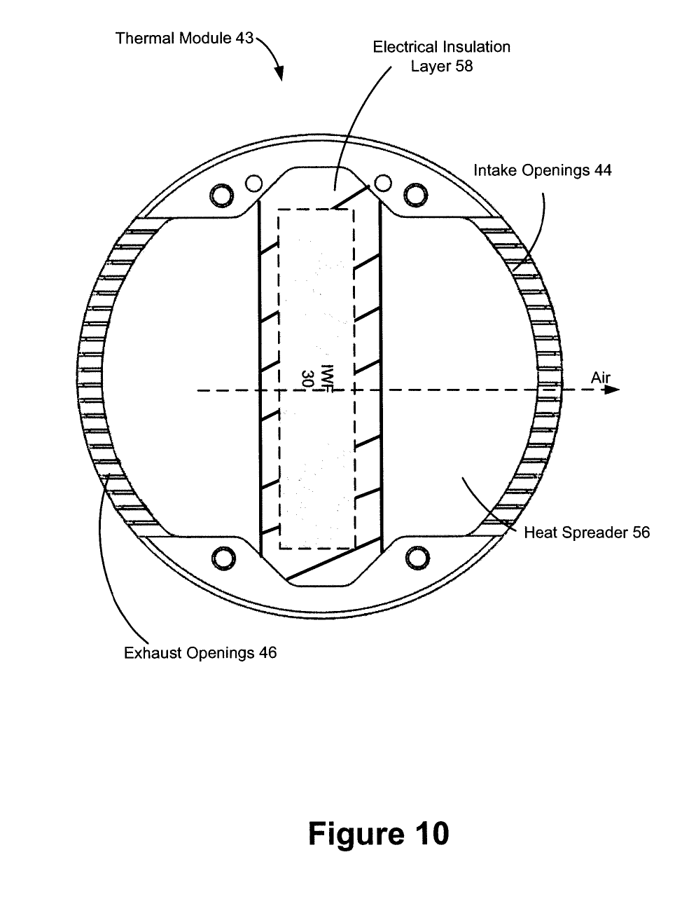

FIGS. 9 and 10 are similar to FIGS. 7 and 8. However, FIGS. 9 and 10 illustrate another embodiment and aspect of the present invention. As shown in FIG. 9, the thermal module 43 includes a heat spreader 56 portion. The LEDs are mounted on the surface of the heat spreader 56 that is not visible in FIG. 9. FIG. 9 shows the air passage channel between the intake 44 and exhaust 46 openings in which the ion wind fan 30 is positioned.

As shown in FIG. 9 and FIG. 10 the thermal module 43 includes an electrical insulation layer 58 in the vicinity of the ion wind fan 30. The electrical insulation layer 58 can be implemented in a variety of ways, such as using a dielectric electrically insulating tape, a plastic dielectric insert or shield, or the electrical insulation layer 56 can be added to the shape of the isolator 34 portion of the ion wind fan 30.

In one embodiment, the electrical insulation layer 58 is provided such that a no metal portions of the heat spreader 56 are within a certain distance from the emitter electrodes 36 of the ion wind fan 30. The predetermined distance is design specific, and depends on the operational voltage of the ion wind fan, among other factors. However, for an ion wind fan operating with a potential difference of about 4-5 kV between the emitters and the collector electrodes, the predetermined distance should be about 4-6 mm.

In one embodiment, the side of the channel opposite the heat spreader 56 is the thermal isolation 48 component, which is dielectric. Thus, in such an embodiment, no additional isolation in required between the thermal isolation 48 and the ion wind fan 30. However, in other embodiments the opposite surface may be also metallic, in which case a similar electrical isolation layer 58 can be used to maintain a minimum requisite distance between the emitter electrodes 58 and the metallic walls of the enclosure/channel.

As used in this Application, the term “enclosure” does not mean a sealed environment, or a space enclosed on all sides. The term enclosure includes any structure that defines a space or channel that an ion wind fan 30 is in. For example, the thermal modules 43 and 80 described in the Application are all enclosures. A rectangular air passage channel having four walls and being open on two ends is also an enclosure. Similarly, a heat spreader and one or more sets of heat sink fins in the vicinity of an ion wind fan would also constitute and enclosure in this context.

The distance between an emitter electrode 36 and the wall of an enclosure or thermal module 43 is measured as the shortest straight line over the air path (as opposed to surface path) between a point on the surface and on the emitter. Thus, for a predetermined distance of 5 mm, no point along the exposed metal surface of the enclosure (heat spreader) can be less than 5 mm away from any point along the nearest emitter electrode.

FIG. 10 illustrates the approximate space of the ion wind fan 30 and one embodiment of the electrical insulation layer 58. In the embodiment illustrated, the electrical insulation layer 58 extends equally upstream and downstream from the ion wind fan 30. However, in other embodiment, the electrical insulation layer 58 can extend further upstream of the ion wind fan than downstream, since the emitter electrodes are located upstream of the collector electrode.

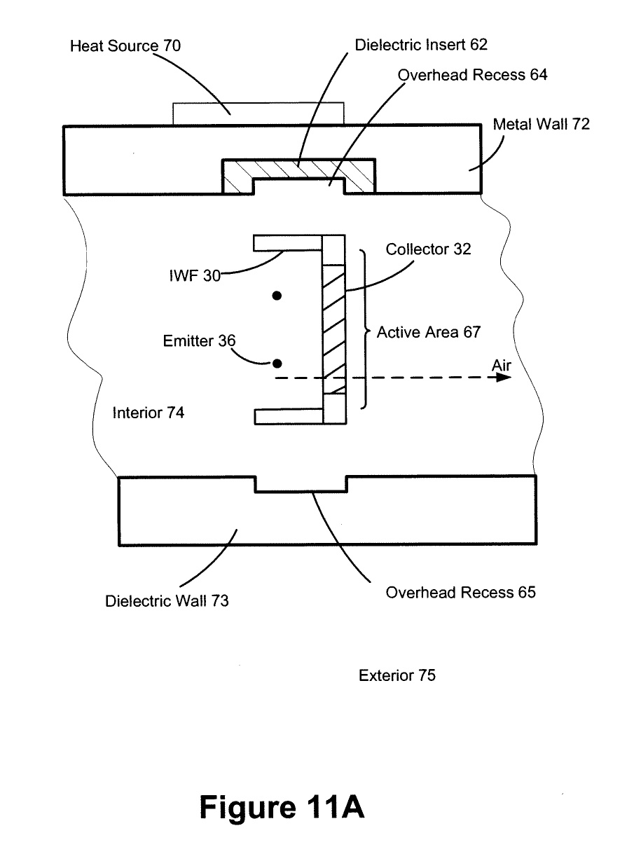

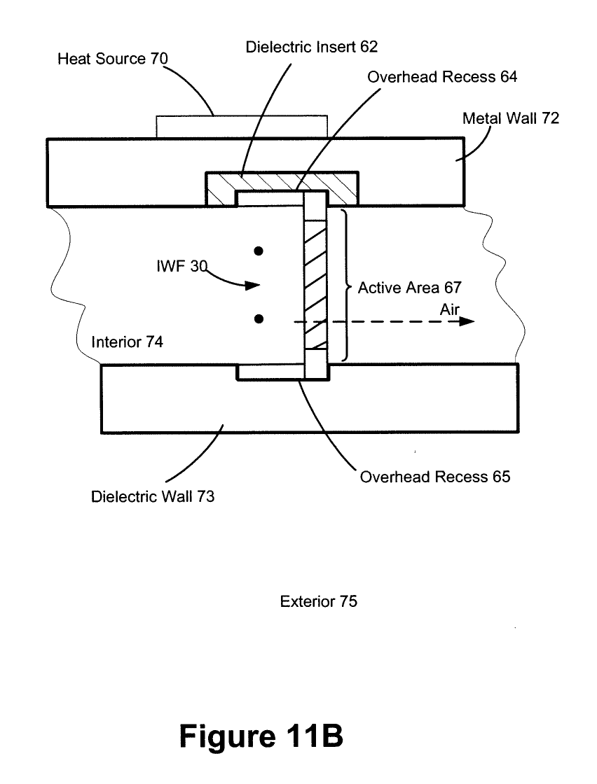

FIGS. 11A and 11B provide a cross-sectional side view of the air passage channel and the ion wind fan, with the direction of airflow being substantially left to right. FIG. 11A is an exploded view and FIG. 11B is the assembled view. In FIG. 11A, the description is generalized to show application to any metallic or partially metallic enclosure or air-passage channel that contains an ion wind fan 30. The enclosure, in one embodiment, has one dielectric wall 73 and one metal wall 72. In this embodiment, the metal wall 72 is also a heat spreader to which a heat source 70 is thermally coupled.

The ion wind fan 30 is shown as having two emitter electrodes 36 and one collector electrode 32, as previously described. In this embodiment, the electrical insulation layer 5 is implemented as a dielectric insert 62. The dielectric insert 62 is proportioned so to keep a minimum distance from the emitter electrodes 36 to the metal wall 72, as measured in a straight over-the-air line. Another aspect of FIGS. 11A and 11B is described further below.

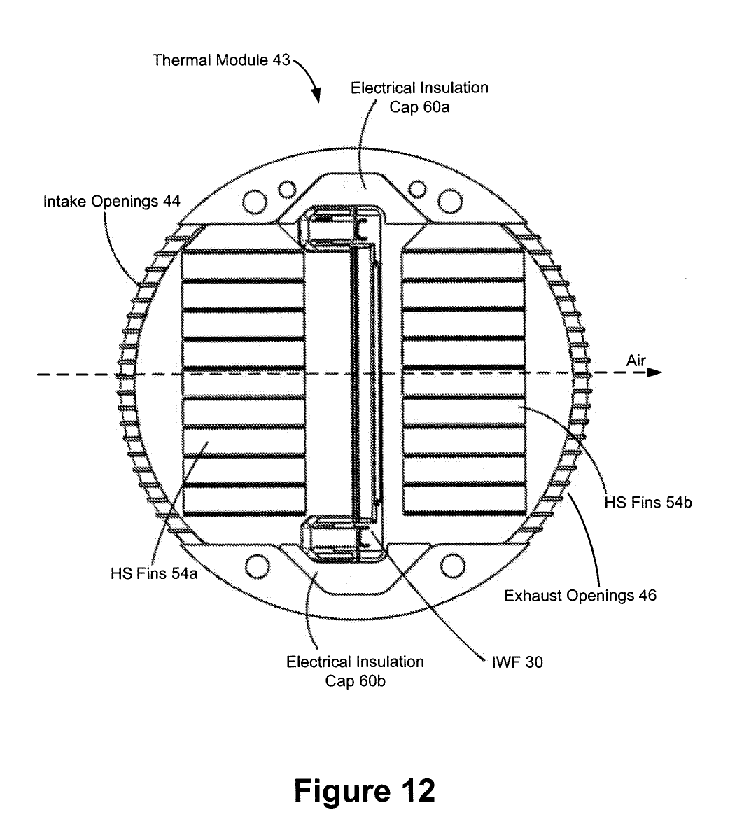

FIG. 12 is another cross-sectional top view of the thermal module 43. In the embodiment shown in FIG. 12, each longitudinal end of the ion wind fan 30 is electrically isolated from the sidewall of the thermal module—i.e. the sides of the air passage channel between the intake 44 and exhaust 46 openings—by two electrical insulation caps 60a,b. One function of the caps 60 is to ensure that the aforementioned predetermined minimum distance is maintained between the emitter electrodes 36 and any metal surface along the side of the air-passage channel.

In one embodiment, the caps 60 also function to guide the airflow from the ion wind fan 30. For example, in FIG. 12, without the caps 60 the shape of the thermal module would be irregular around the ends of the ion wind fan 30. In one embodiment, the caps 60 can be formed integrally with the isolator 34 element, and thus be included in the shape of the isolator. However, such inclusion can make the ion wind fans 30 too bulky, too specific, or more difficult to handle during manufacture. Thus, in the embodiment shown, the caps are physically separate from the isolator 34, but designed to mate with both the isolator 34 and the thermal module 43.

Notched Enclosures

Another embodiment of a present invention is now described with reference yet again to FIGS. 11A and 11B. In one embodiment, the “active” area of the ion wind fan 30 is smaller than the surface of the collector electrode 32 or the isolator 34. The active area can be defined as the downstream area of the ion wind fan 30 that substantially contributes to the airflow generated by the ion wind fan 30. In other embodiments, the entire frontal (downstream) area of the ion wind fan 30 is active.

In the embodiment shown in FIG. 11, active area 67 of the ion wind fan 30 is smaller than the total area of the ion wind fan 30. In one embodiment, overhead recesses are provided both to maximize the size of the active area 67 relative to the air passage channel (the interior 74 of the enclosure) and to smooth out the channel for the airflow by avoiding low-pressure areas immediately downstream of the collector electrode 32. As shown in FIG. 11B, because of the overhead recesses, the active area 67 of the ion wind fan is approximately matched with the dimensions of the air passage channel in which the ion wind fan 30 generates the airflow.

In FIG. 11, the overhead recesses 64,65 are notches or grooves having a shape that mate with the elongated side-members of the isolator 34 shown in FIG. 2. The notches extend in the longitudinal direction of the ion wind fan 30. The depth of the notches or grooves is such that they approximately absorb the inactive/overhead area of the ion wind fan that extends in the longitudinal direction. The overhead areas along the ends of the ion wind fan 30 can be absorbed into similar notches or grooves on the end caps 60 as shown in FIG. 12. The depth of the overhead recesses is thus implementation specific, but in one embodiment, they are about 1-3 mm deep and have a width and length corresponding with the sides of the ion wind fan 30 so that the ion wind fan 30 mates with the overhead recesses, as shown in FIGS. 11A and 11B.

In one embodiment, the overhead recess 64 in the metal wall 72 is formed in the dielectric insert 62 that electrically isolates the emitter electrodes 36 from the metal wall 72, as described further above. In another embodiment, the dielectric insert 62 can be integral with the isolator 34, in which case the groove into which the dielectric insert 62 is inserted becomes the overhead recess 64. In other embodiments, such as in dielectric wall 73, the overhead recess 65 need not perform electrical isolation functionality.

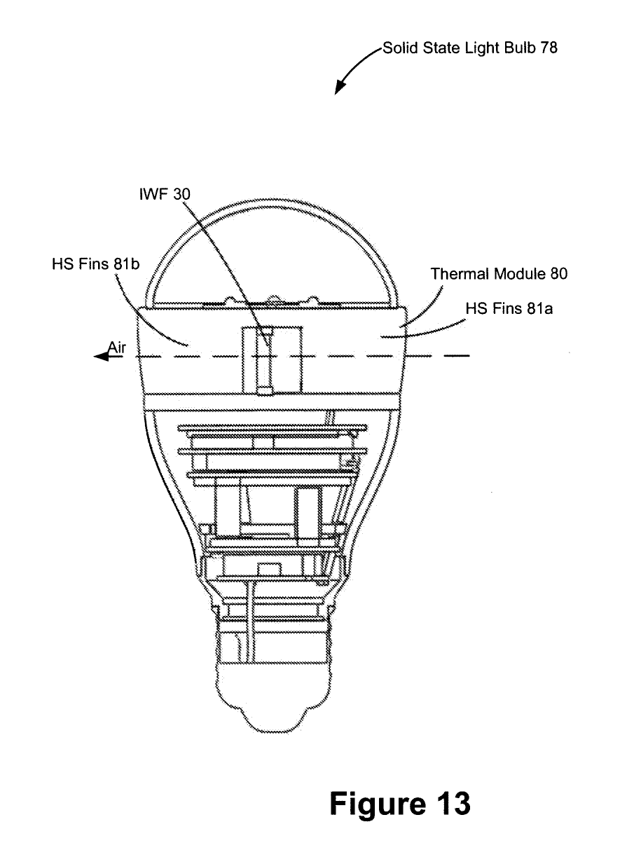

FIGS. 13-17 illustrate alternate embodiments of a thermal module 80. All of the various embodiments of the various inventions described above can be implemented in combination with the thermal module 80. In one embodiment, one difference between thermal modules 80 and thermal modules 43 is that in thermal module 80 the heat spreader plate and heat sink fins 81 portions of the thermal module 80 is made of one integral piece of metal. This can be sometimes referred to as a monolithic thermal module or monolithic heat sink. Such a thermal module 80 can be machined, cast, or manufactured using various other heat sink manufacturing techniques.

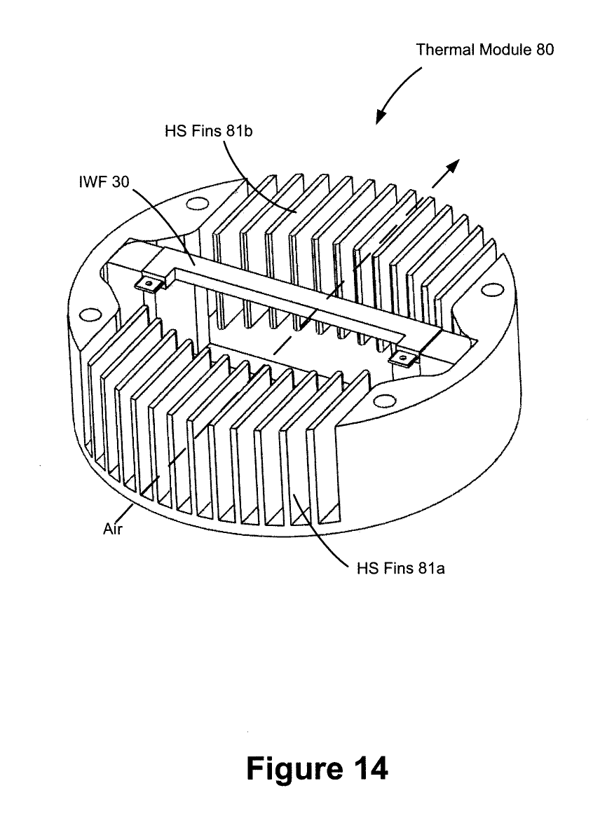

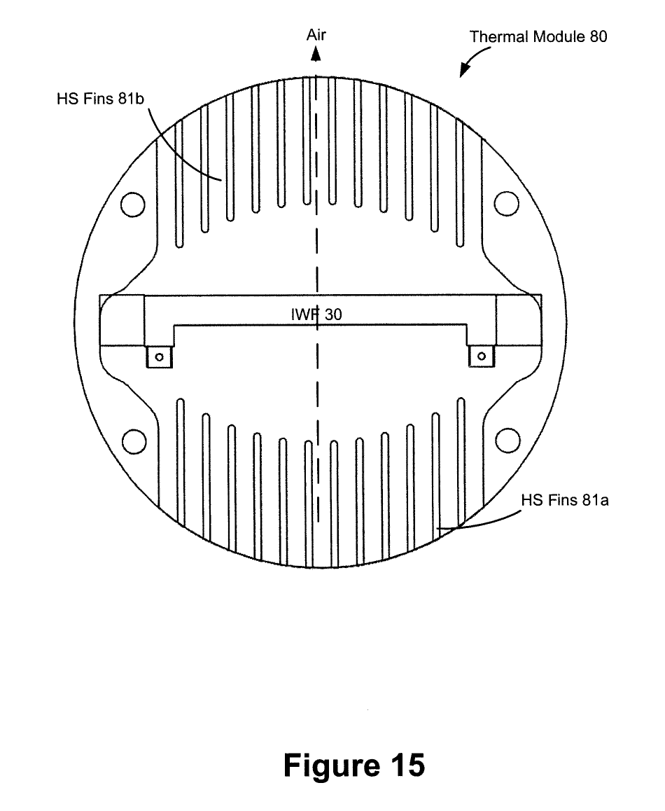

FIGS. 14 and 15 shown a monolithic thermal module 80 having an ion wind fan 30 and straight fins 81 and straight channels defined by the fins 81. The fins are all equal or approximately equal in length. Since the heat spreader is round, in one embodiment, this causes the fins 81 to be a variable distance away from the ion wind fan 30. As can be seen in FIG. 15, the distance from the downstream side of the ion wind fan 30 to the downstream heat sink fins 81b is greatest around the center of the ion wind fan 30, and gets progressively smaller moving towards the ends of the ion wind fan 30. The upstream heat sink fins 81a have a similar configuration.

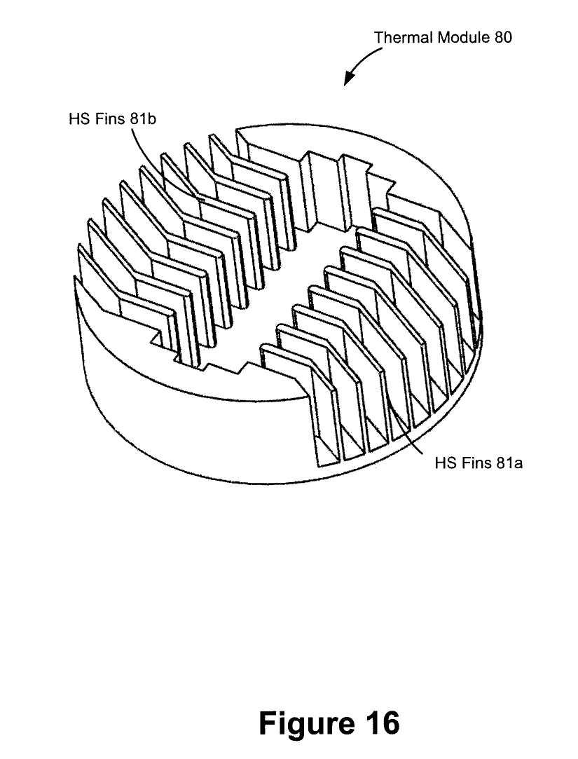

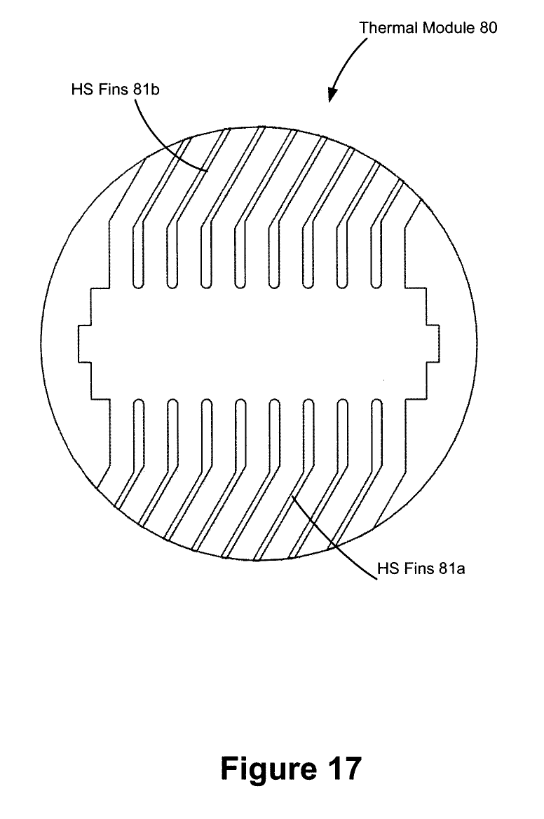

In another embodiment, the heat sink fins 81 are equidistant from the ion wind fan 30 and have variable length to conform to the round shape of the heat spreader. For example, the fins 81 shown in FIGS. 16 and 17 have such a configuration. Another aspect of the fins shown in FIGS. 16 and 17 is that they form channels having a angled bend. The fins 81 all have a bend that prevents a straight line of sight from the outside of the thermal module 80 to the ion wind fan 30 inside of the thermal module 80. In one embodiment, all fins are bent at the same angle in the range of 15-40 degrees, but other ranges can be used as well, and not all fins need the same degree of bending.

In the descriptions above, various functional modules are given descriptive names, such as “ion wind fan power supply,” and “thermal module.” The functionality of these modules can be implemented in software, firmware, hardware, or a combination of the above, where appropriate. None of the specific modules or terms—including “power supply” or “ion wind fan”—imply or describe a physical enclosure or separation of the module or component from other system components.

Furthermore, descriptive names such as “emitter electrode,” “collector electrode,” and “isolator,” are merely descriptive and can be implemented in a variety of ways. For example, the “collector electrode,” can be implemented as one piece of metallic structure (as shown in the FIG. 5C, for example), but it can also be made of multiple members spaced apart, and connected by wires or other electrical connections to the same voltage potential, such as ground.

Similarly, the isolator can be the substantially frame-like component shown in FIG. 2A, but it can have various shapes. The electrodes and the isolator are not limited to any particular material; however, the isolator will generally be made of a dielectric material, such as plastic, ceramic, and other known dielectrics. Thus in one embodiment, any of the collector electrodes discussed herein can be substituted for the collector electrode 32 of FIG. 2A to create an ion wind fan according to an embodiment of the present invention. In other embodiments, other isolator designs can be used, as long as it establishes substantially the same spatial relationships between the electrodes.

1. An apparatus comprising:
a heat source;
a heat spreader thermally coupled to the heat source, wherein the heat spreader comprises one or more walls of an enclosure; and
an ion wind fan located inside the enclosure, the ion wind fan comprising a collector electrode and one or more emitter electrodes;
wherein a first portion of a surface of the heat spreader is electrically isolated from the ion wind fan, the first portion being less than a minimum predetermined distance from the one or more emitter electrodes.

2. The apparatus of claim 1, wherein the ion wind fan has a potential difference between 3 kilovolts and 6 kilovolts between the emitter and collector electrodes when operational, and the minimum predetermined distance is in the range of 4-9 millimeter.

3. The apparatus of claim 1, wherein the heat spreader comprises a first surface and a second surface opposite the first surface, and wherein the heat source is thermally coupled to the first surface and the first portion comprises a first portion of the second surface.

4. The apparatus of claim 1, wherein the first portion of the heat spreader comprises a dielectric insert.

5. The apparatus of claim 1, wherein the first portion of the heat spreader comprises a dielectric tape or coating.

6. The apparatus of claim 1, wherein the heat spreader has a round disk shape.

7. The apparatus of claim 6, wherein the enclosure has a rectangular shape.

8. The apparatus of claim 1, wherein the apparatus comprises an LED light bulb and the heat source comprises an LED module.

9. An apparatus comprising:
a heat source;
a heat spreader having a first surface and a second surface, wherein the heat source is thermally coupled to the first surface, and wherein a plurality of fins are thermally coupled to the second surface; and
an ion wind fan oriented to generate an airflow over the fins;
wherein a first portion of the second surface of the heat spreader is electrically isolated from the ion wind fan, wherein the plurality of fins do not contact the heat spreader at the first portion of the second surface.

10. The apparatus of claim 9, wherein the first portion of the second surface comprises a dielectric insert.

11. The apparatus of claim 9, wherein the ion wind fan comprises an emitter, a collector, and an isolator that electrically isolates the emitter from the collector, wherein the isolator is also configured to electrically isolate the first portion of the second surface from the ion wind fan.

12. A heat sink comprising:
a heat spreader to thermally couple to a heat source;
a first set of fins extending from the heat spreader;
a second set of fins extending from the heat spreader, wherein the first and second set of fins define a fan area between where no fins extend from the heat spreader; and
an ion wind fan located in the fan area, wherein the fan area of the heat spreader is electrically isolated from the ion wind fan.

13. A solid-state light bulb having a substantially round cross-section, the solid-state light bulb comprising:
a bulb body having one or more air intake openings and one or more air exhaust openings, the bulb body defining an air passage channel between the air intake and the air exhaust openings,
an ion wind fan located inside the air passage channel and configured to generate an airflow from the air intake towards the air exhaust openings, the ion wind fan having a longitudinal axis, a first end, and a second end longitudinally opposite the first end;
a first end cap coupled to the first end of the ion wind fan, the first end cap comprising a dielectric, wherein the first end cap electrically isolates the first end of the ion wind fan from a first wall of the air passage channel.

14. The solid-state light bulb of claim 13, wherein the first end cap has a shape that guides the air within the air passage channel.

15. The solid-state light bulb of claim 13, wherein the air passage channel comprises a second wall, the second comprising a dielectric in the vicinity of the ion wind fan.

16. The solid-state light bulb of claim 15, wherein the vicinity of the ion wind fan comprises at least 5 mm from the emitter electrodes of the ion wind fan.
